(19) United States
(12) Patent Application Publication
(10) Pub. No.: US 2025/0155821 A1
(43) Pub. Date: May 15, 2025

(54) APPARATUS FOR AND METHOD OF CONDITIONING LASER ELECTRODES

(71) Applicant: Cymer, LLC, San Diego, CA (US)

(72) Inventors: Yuda Wang, San Diego, CA (US); Paul Christopher Melcher, San Diego, CA (US); Changqi You, San Diego, CA (US); Andrew Jay Effenberger, San Diego, CA (US)

(21) Appl. No.: 18/695,193

(22) PCT Filed: Sep. 14, 2022
(86) PCT No.: PCT/US2022/043488

§ 371 Date: Mar. 25, 2024

Related U.S. Application Data
(60) Provisional application No. 63/270,187, filed on Oct. 21, 2021.

(51) Int. Cl. G03F 7/00; H01S 3/038

(52) U.S. Cl. CPC G03F 7/70041; G03F 7/70025; H01S 3/0381; H01S 3/0382

(57) ABSTRACT

Disclosed are apparatus for and methods of passivating a first electrode normally serving as a cathode in a laser discharge chamber also including a second electrode normally serving as an anode by supplying reversed polarity pulses to the first electrode either during part of a chamber manufacturing passivation procedure or intermittently or on demand after the chamber has been put in service.

### CROSS REFERENCE TO RELATED APPLICATIONS

This application claims priority to U.S. Application No. 63/270,187, filed Oct. 21, 2021, titled APPARATUS FOR AND METHOD OF CONDITIONING LASER ELECTRODES, which is incorporated herein in its entirety by reference.

### FIELD

The present disclosed subject matter relates to laser-generated light sources such as are used for integrated circuit photolithographic manufacturing processes.

### BACKGROUND

In deep ultraviolet (“DUV”) laser sources, pulses of laser radiation are generated by causing a plasma discharge to occur between electrodes in a discharge chamber. Conventional DUV chambers are fired with negative polarity with a lower electrode at ground potential at the bottom of the discharge chamber and an upper electrode receiving a pulse of a high negative voltage at the top of the discharge chamber. This arrangement is used in manufacturing during initial electrode passivation. It is also the arrangement used in actual operation of the chamber in the field. Here and elsewhere the terms “upper” and “lower” are used to indicate the relative positions of the electrodes and not necessarily their positions with respect to gravity, although the electrodes may be arranged so that “upper” and “lower” also corresponds to their position with respect to gravity.

These lasers are typically configured to generate sequences of pulses called bursts. One operational parameter for such chambers is the amount of laser energy generated as a function of the electrical voltage applied across the electrodes. For an efficient laser, there should be as much energy generated for a given potential difference between the electrodes as possible.

Another criterion for assessing the performance of the laser chamber is the stability of energy production as a function of the voltage across the electrodes. In other words, it is generally desirable that the amount of laser radiation energy generated by a given electrode voltage remain as constant as possible over time. As the laser chamber and its electrodes mature, however, there is a tendency for the energy versus voltage relationship to change, leading to energy voltage instability (EVI). It is desirable to limit the energy variation for a given potential difference both burst-to-burst and pulse-to-pulse.

One cause of EVI is the tendency of the discharge in the discharge chamber to concentrate and form transient electrical discharges at the surfaces of the conductive electrode, i.e., a filamentary discharges or streamers. This process steals energy from the plasma that generates the laser radiation. It also leads to unpredictable variations in the energy versus voltage relationship. Therefore, reducing streamers can lead to a reduction in EVI.

The streamers tend to form at locations on electrode surfaces that have been damaged by various mechanisms. One measure to mitigate this damage is to condition the electrode surface to make it less susceptible to such damage, e.g., to passivate the discharge surface of the electrode. Passivation typically involves exposing the discharge surface to a flux of electrons and negative ions (e.g., F⁻).

Passivation is part of the process of preparing the electrodes for service by applying negative pulses to the cathode to passivate the cathode and anode. Passivation tends to occur preferentially (more quickly and completely) on the positive anode and not as well on the negative cathode, even when the anode and cathode are made of similar materials. It thus generally takes more time (i.e., more pulses) to passivate the cathode than it does the anode.

In the field, some passivation occurs innately during use. Again, however, the anode benefits more from this innate passivation than does the cathode. Thus the cathode is more prone to generating streamers.

It is therefore desirable to be able to provide an arrangement for laser electrodes in which the electrodes can be conditioned more rapidly during manufacturing. It is also desirable to be able to enhance innate passivation on electrode discharge surfaces after a chamber has been deployed to the field. It is in this context that the need for the present invention arises.

### SUMMARY

The following presents a succinct summary of one or more embodiments in order to provide a basic understanding of the present invention. This summary is not an extensive overview of all contemplated embodiments and is not intended to identify key or critical elements of all embodiments nor delineate the scope of any or all embodiments. Its sole purpose is to present some concepts of one or more embodiments in a streamlined form as a prelude to the more detailed description that is presented later.

According to one aspect, the subject matter of the present disclosure improves passivation of the cathode by reversing the polarity of the discharge. Thus the upper electrode functions as the anode during periods of reversed polarity discharge.

According to an aspect of an embodiment, there is disclosed a pulsed power supply for a laser discharge chamber including a first electrode and a second electrode, the pulsed power supply having a first state in which it generates and supplies to the first electrode at least one pulse having a first polarity and a second state in which the pulsed power supply generates and supplies to the first electrode at least one reverse polarity pulse having a second polarity, the second polarity being opposite to the first polarity. The power supply may be adapted to transition between the first state and the second state in response to a control signal.

According to another aspect of an embodiment, there is disclosed a laser comprising a discharge chamber, a first electrode positioned at least partially within the discharge chamber, a second electrode positioned at least partially within the discharge chamber, the first electrode having a first discharge surface and the second electrode having a second discharge surface, the first discharge surface and the second discharge surface being arranged to confront one another across a gap and a pulsed power supply arranged to generate and supply pulses of electrical energy to the first electrode, wherein the pulsed power supply has a first state in which it generates and supplies to the first electrode at a first plurality of pulses having a first polarity and a second state in which the pulsed power supply generates and supplies to the first electrode a second plurality of pulses having a second polarity, the second polarity being opposite to the first polarity.

The laser may further comprise a metrology unit arranged to measure and produce an EVI characteristic of the first plurality of pulses, and a control unit arranged to receive the output and adapted to generate a control signal based on the EVI characteristic of the EVI of the first plurality of pulses, with the pulsed power supply being arranged to receive the control signal and adapted to transition from the first state to the second state in response to the control signal. The characteristic of the EVI may be a magnitude of the EVI. The characteristic of the EVI may be a frequency of the EVI.

According to another aspect of an embodiment, there is disclosed a laser comprising a discharge chamber, an upper electrode positioned at least partially within the discharge chamber, a lower electrode positioned at least partially within the discharge chamber, the upper electrode having an upper electrode discharge surface and the lower electrode having a lower electrode discharge surface, the upper electrode discharge surface and the lower electrode discharge surface being arranged to confront one another across a gap, and a pulsed power supply arranged to generate and supply pulses of electrical energy to the upper electrode, the pulsed power supply having a first state in which the pulsed power supply generates and supplies to the upper electrode a plurality of negative-going pulses and a second state in which the pulsed power supply generates and supplies to the upper electrode a plurality of positive-going pulses.

The laser may further comprise a metrology unit arranged to measure and produce an output indicative of an EVI of the laser, and a control unit arranged to receive the output and adapted to generate a control signal based on an EVI characteristic voltage of the plurality of negative-going pulses, with the pulsed power supply being arranged to receive the control signal and adapted to transition from the first state to the second state in response to the control signal.

According to another aspect of an embodiment, there is disclosed a method of operating a pulsed power supply for a laser discharge chamber including a first electrode and a second electrode, comprising causing the pulsed power supply to operate in a first state in which it generates and supplies to the first electrode at least one pulse having a first polarity, and causing the pulsed power supply to transition to a second state in which the pulsed power supply generates and supplies to the first electrode at least one reverse polarity pulse having a second polarity, the second polarity being opposite to the first polarity. Causing the pulsed power supply to transition to the second state may comprise receiving a control signal.

According to another aspect of an embodiment, there is disclosed a method of operating a laser, the laser comprising a discharge chamber; a first electrode positioned at least partially within the discharge chamber, and a second electrode positioned at least partially within the discharge chamber, the first electrode having a first discharge surface and the second electrode having a second discharge surface, the first discharge surface and the second discharge surface being arranged to confront one another across a gap, and a pulsed power supply arranged to provide pulses of electrical energy to the first electrode, the method comprising causing the pulsed power supply to operate in a first mode in which the pulsed power supply supplies the first electrode with a first sequence of pulses having a first polarity, and causing the pulsed power supply to transition to operate in a second mode in which the pulsed power supplies to the first electrode at second sequence of pulses having a second polarity, the second polarity being opposite to the first polarity.

The method may further comprise measuring and producing an output indicative of an EVI characteristic of the laser and generating a control signal based on the output and an EVI characteristic of the first sequence of pulses, wherein causing the pulsed power supply to transition comprises the pulsed power supply receiving the control signal and transitioning from the first mode to the second mode in response to the control signal.

According to another aspect of an embodiment, there is disclosed a method of operating a laser, the laser including a discharge chamber, an upper electrode positioned at least partially within the discharge chamber, and a lower electrode positioned at least partially within the discharge chamber, the cathode having an upper electrode discharge surface and the anode having a lower electrode discharge surface, the cathode discharge surface and the anode discharge surface being arranged to confront one another across a gap, and a pulsed power supply arranged to generate and supply pulses of electrical energy to the cathode, the method comprising causing the pulsed power supply to operate in a first mode in which the pulsed power generates and supplies to the cathode a plurality of negative-going pulses, and causing the pulsed power supply to transition to a second mode in which the pulsed power supply generates and supplies to the cathode a plurality of positive-going pulses.

The method may further comprise measuring and producing an output indicative of an EVI characteristic of the laser and generating a control signal based on an EVI characteristic of the plurality of the negative-going pulses, wherein the pulsed power supply is arranged to receive the control signal and adapted to transition from the first mode to the second mode in response to the control signal.

According to another aspect of an embodiment, there is disclosed a method of conditioning a first electrode and a second electrode, comprising causing a pulsed power supply to supply a first sequence of pulses having a first polarity to the first electrode, and causing the pulsed power supply to supply a second sequence of pulses to the first electrode, the pulses in the second sequence of pulses having a second polarity, the second polarity being opposite to the first polarity. The number of pulses having the first polarity applied during conditioning may be in a predetermined ratio to a number of pulses having the second polarity applied during conditioning.

According to another aspect of an embodiment, there is disclosed a method a conditioning an electrode to be conditioned for use in a chamber, the method comprising providing a test rig including an upper electrode and a pulsed power supply connected to supply negative-going pulses to the upper electrode, placing the electrode to be conditioned in the test rig and connecting the electrode to be conditioned to the pulsed power supply as a lower electrode, applying pulses to the upper electrode to passivate the electrode to be conditioned to create a conditioned electrode, removing the conditioned electrode from the test rig, and installing the conditioned electrode in the chamber as an upper electrode or a lower electrode.

According to another aspect of an embodiment there is disclosed a pulsed power supply system for a laser discharge chamber including a first electrode and a second electrode, the pulsed power supply system comprising a pulsed power supply adapted to have a first state in which the pulsed power supply generates and supplies to the first electrode a first plurality of pulses having a first polarity and a second state in which the pulsed power supply generates and supplies to the first electrode a second plurality of pulses having a second polarity, the second polarity being opposite to the first polarity, a metrology unit arranged to measure and produce an output indicative of at least one characteristic of an EVI of at least some of first plurality of pulses, and a control unit arranged to receive the output and adapted to generate a control signal based at least in part on the output, wherein the pulsed power supply is arranged to receive the control signal and adapted to transition from the first state to the second state in response to the control signal.

The at least one characteristic of the EVI may be a magnitude of the EVI. The at least one EVI characteristic may be a frequency of occurrence of the EVI.

Further embodiments, features, and advantages of the subject matter of the present disclosure, as well as the structure and operation of the various embodiments, are described in detail below with reference to accompanying drawings.

### BRIEF DESCRIPTION OF THE DRAWINGS

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 is a schematic, not to scale, view of an overall broad conception of a photolithography system according to an aspect of the disclosed subject matter.

FIG. 2 is a schematic, not to scale, view of an overall broad conception of an illumination system according to an aspect of the disclosed subject matter.

FIG. 3 is a diagrammatic cross section, not to scale, of a discharge chamber for an excimer laser according to aspects of the disclosed subject matter.

FIG. 4 is a functional block diagram of a pulsed power supply for the discharge chamber for an excimer laser according to aspects of the disclosed subject matter.

FIG. 5 is a circuit diagram of a pulsed power supply for the discharge chamber for an excimer laser according to aspects of the disclosed subject matter.

FIG. 6 is a graph showing pulse voltage as a function of time for the discharge chamber for an excimer laser.

FIG. 7 is a graph showing pulse voltage as a function of time for the discharge chamber for an excimer laser according to aspects of the disclosed subject matter.

FIG. 8A is a partially schematic functional block diagram of an arrangement for electrode conditioning according to aspects of the disclosed subject matter.

FIG. 8B is a partially schematic functional block diagram of an arrangement for electrode conditioning according to aspects of the disclosed subject matter.

FIG. 8C is a partially schematic functional block diagram of an arrangement for electrode conditioning according to aspects of the disclosed subject matter.

FIG. 9 is a partially schematic functional block diagram of another arrangement for conditioning an electrode according to aspects of the disclosed subject matter.

FIG. 10 is a flowchart of a method of conditioning electrodes for a discharge chamber of an excimer laser according to aspects of the disclosed subject matter.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. This summary is not an extensive overview of all contemplated embodiments and is not intended to identify key or critical elements of all embodiments nor delineate the scope of any or all embodiments.

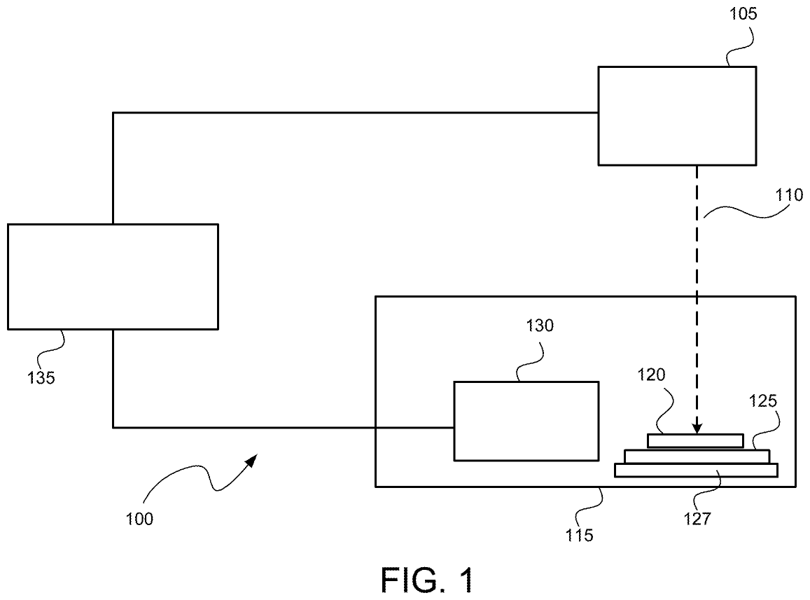

FIG. 1 shows a photolithography system 100 that includes an illumination system 105. As described more fully below, the illumination system 105 includes a light source that produces a pulsed light beam 110 and directs it to a photolithography exposure apparatus or scanner 115 that patterns microelectronic features on a wafer 120. The wafer 120 is placed on a wafer table 125 constructed to hold wafer 120 and connected to a positioner 127 configured to accurately position the wafer 120 in accordance with certain parameters.

The photolithography system 100 uses a light beam 110 having a wavelength in the deep ultraviolet (DUV) range, for example, with a wavelength of 248 nanometers (nm) or 193 nm. The minimum size of the microelectronic features that can be patterned on the wafer 120 depends on the wavelength of the light beam 110, with a shorter wavelength permitting a smaller minimum feature size. The scanner 115 includes an optical arrangement having, for example, one or more condenser lenses, a mask, and an objective arrangement. The mask is movable along one or more directions, such as along an optical axis of the light beam 110 or in a plane that is perpendicular to the optical axis. The objective arrangement includes a projection lens and enables the image transfer to occur from the mask to photoresist on the wafer 120. The illumination system 105 adjusts the range of angles for the light beam 110 impinging on the mask. The illumination system 105 also homogenizes (makes uniform) the intensity distribution of the light beam 110 across the mask.

The scanner 115 can include, among other features, a lithography controller 130 that controls how layers are printed on the wafer 120. The lithography controller 130 includes a memory that stores information such as process recipes that determine the length of the exposure on the wafer 120 based on, for example, the mask used, as well as other factors that affect the exposure. During lithography, a plurality of pulses of the light beam 110 illuminates the same area of the wafer 120 to constitute an illumination dose.

The photolithography system 100 also preferably includes a control system 135. In general, the control system 135 includes one or more of digital electronic circuitry, computer hardware, firmware, and software. The control system 135 also includes memory which can be read-only memory and/or random access memory. Storage devices suitable for tangibly embodying computer program instructions and data include all forms of non-volatile memory, including, by way of example, semiconductor memory devices, such as EPROM, EEPROM, and flash memory devices; magnetic disks such as internal hard disks and removable disks; magneto-optical disks; and CD-ROM disks.

The control system 135 can also include one or more input devices (such as a keyboard, touch screen, microphone, mouse, hand-held input device, etc.) and one or more output devices (such as a speaker or a monitor). The control system 135 can also include one or more programmable processors, and one or more computer program products tangibly embodied in a machine-readable storage device for execution by one or more programmable processors. The one or more programmable processors can each execute a program of instructions to perform desired functions by operating on input data and generating appropriate output. Generally, the processors receive instructions and data from the memory. Any of the foregoing may be supplemented by, or incorporated in, specially designed ASICs (application-specific integrated circuits). The control system 135 can be centralized or be partially or wholly distributed throughout the photolithography system 100.

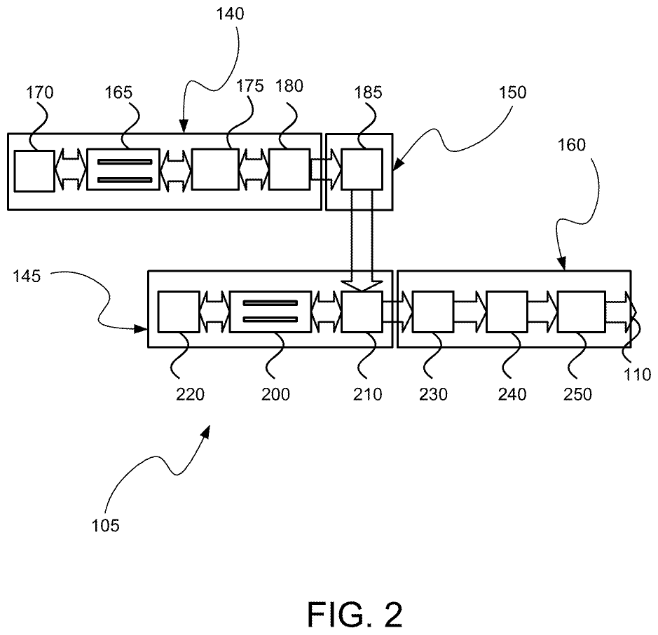

FIG. 2 shows a pulsed laser source that produces a pulsed laser beam as the light beam 110 as an example of an illumination system 105. FIG. 2 shows a two-chamber laser system as a nonlimiting example but it will be understood that the principles explained herein are equally applicable to a single chamber laser system. The gas discharge laser system may include, e.g., a solid state or gas discharge seed laser system 140, an amplification stage, e.g., a power ring amplifier (“PRA”) stage 145, relay optics 150 and laser system output subsystem 160. The seed system 140 may include, e.g., a master oscillator (“MO”) chamber 165 which includes a pair of electrodes as described below.

The seed laser system 140 may also include a master oscillator output coupler (“MO OC”) 175, which may comprise a partially reflective mirror, forming with a reflective grating (not shown) in a line narrowing module (“LNM”) 170, an oscillator cavity in which the seed laser 140 oscillates to form the seed laser output pulse, i.e., forming a master oscillator (“MO”). The system may also include a line-center analysis module (“LAM”) 180. A MO wavefront engineering box (“WEB”) 185 may serve to redirect the output of the MO seed laser system 140 toward the amplification stage 145, and may include, e.g., beam expansion with, e.g., a multi prism beam expander (not shown) and an optical delay path (not shown).

The amplification stage 145 may include, e.g., a PRA lasing chamber 200, which may also be an oscillator, e.g., formed by seed beam injection and output coupling optics (not shown) that may be incorporated into a PRA WEB 210 and may be redirected back through the gain medium in the chamber 200 by a beam reverser 220. The PRA WEB 210 may incorporate a partially reflective input/output coupler (not shown) and a maximally reflective mirror for the nominal operating wavelength (e.g., at around 193 nm for an ArF system) and one or more prisms. The lasing chamber 200 may also include a pair of electrodes as described below.

A bandwidth analysis module (“BAM”) 230 at the output of the amplification stage 145 may receive the output laser light beam of pulses from the amplification stage and pick off a portion of the light beam for metrology purposes, e.g., to measure the output bandwidth and pulse energy. The laser output light beam of pulses then passes through an optical pulse stretcher (“OPuS”) 240 and an output combined autoshutter metrology module (“CASMM”) 250, which may also be the location of a pulse energy meter. One purpose of the OPuS 240 may be, e.g., to convert a single output laser pulse into a pulse train. Secondary pulses created from the original single output pulse may be delayed with respect to each other. By distributing the original laser pulse energy into a train of secondary pulses, the effective pulse length of the laser can be expanded and at the same time the peak pulse intensity reduced. The OPuS 240 can thus receive the laser beam from the PRA WEB 210 via the BAM 230 and direct the output of the OPuS 240 to the CASMM 250.

The PRA lasing chamber 200 and the MO 165 are configured as chambers in which electrical discharges between electrodes cause lasing gas discharges in a lasing gas to create an inverted population of high energy molecules, including, e.g., Ar, Kr, F₂, and/or Xe, to produce relatively broad band radiation that may be line narrowed to a relatively very narrow bandwidth and center wavelength selected in the LNM 170, as is known in the art.

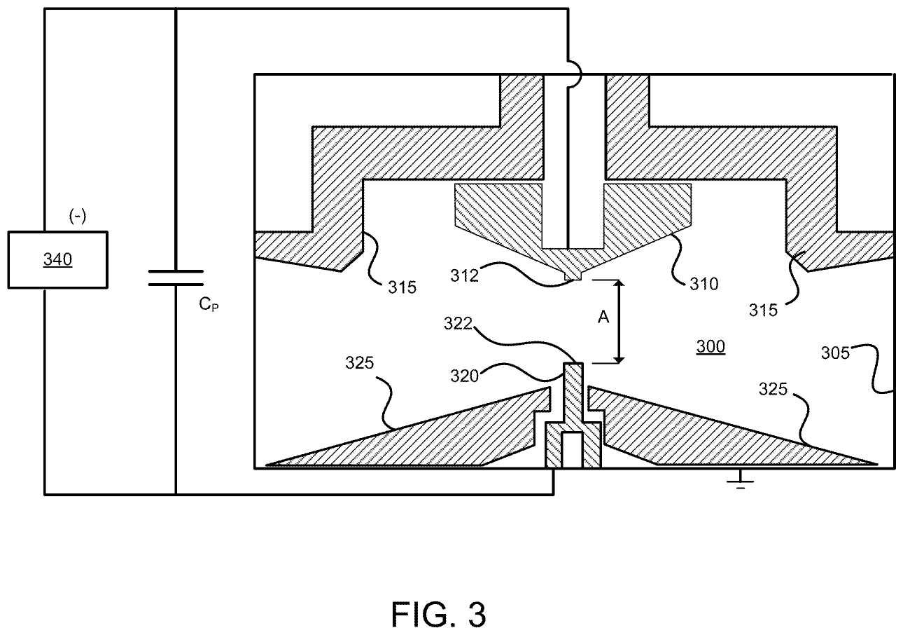

A configuration for a discharge chamber 300 such as may serve as a PRA lasing chamber 200 or the MO 165 is shown in FIG. 3. A chamber 300 includes an upper electrode 310 acting as a cathode and a lower electrode 320 acting as an anode. One or both of the lower electrode 320 and the upper electrode 310 may be entirely contained in the pressure envelope of chamber 300 defined by the chamber wall 305 or one or both of the electrodes may not be so contained. Cₚ is a peaking capacitor (which may be a bank of capacitors in parallel mounted on top of and as a part of the laser chamber 300) electrically connected in parallel with the laser system electrodes 310, 320.

Also shown in FIG. 3 are an upper insulator 315 and a lower insulator 325. The lower electrode 320 is typically electrically connected to the wall 305 of the chamber 300. For safety reasons it is desirable to maintain the chamber wall 305 and so the lower electrode 320 at ground potential. In the embodiment shown in FIG. 3, the upper electrode 310 is driven by a voltage supply 340 at a voltage which is negative with respect to the lower electrode 320. Thus, in this configuration the upper electrode is functioning as a cathode and the lower electrode is functioning as an anode.

As mentioned, also shown in FIG. 3 is a voltage supply 340 which establishes a pulsed voltage gradient across cathode 310 and anode 320. While the notation (−) is shown for the polarity of the output of the voltage supply 340 it will be understood that this is a relative rather than absolute polarity, that is, relative to the polarity of the lower electrode 320. The upper electrode (cathode 310) is charged to a large (e.g., 20 kV) negative voltage.

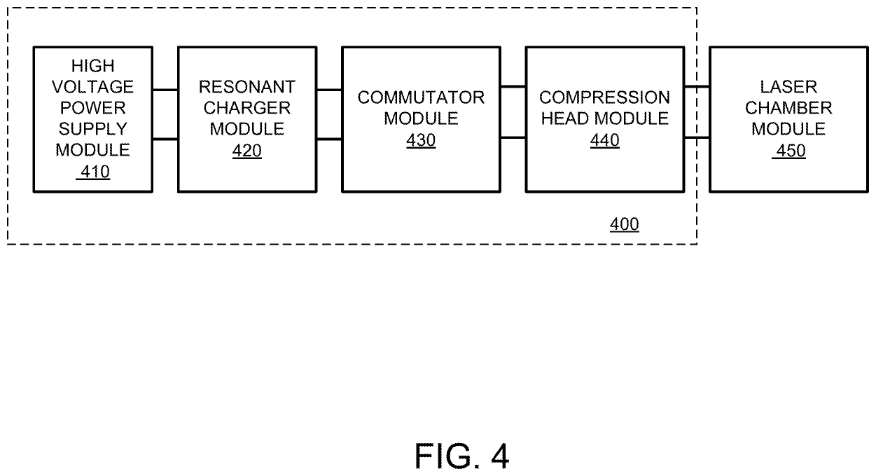

FIG. 4 is a functional block diagram of an example of a pulsed power supply 400 that includes a high voltage power supply module 410, a resonant charger module 420, a commutator module 430, and a compression head module 440. Pulsed power circuit 400 may be used to generate short and powerful pulses (e.g., in the 60-150 ns range and typical energy of 2-3 J per pulse) of electrical power. The electrical pulses may be supplied to the peaking capacitor Cₚ and electrodes in a laser chamber as discharge pulses in order to generate light pulses from the laser.

The output of the compression head module 440 may be supplied, for example, to a laser chamber module 450 which may be, for example, one chamber (MO or PA) of a dual chamber system. In general, each discharge chamber is provided with its own respective pulsed power circuit 400. The pulsed power circuit 400 for each chamber, however, may share various elements such as a shared high voltage power supply module 410 and resonant charger module 420. The pulsed power circuit 400 may be configured as a solid state pulsed power module (SSPPM).

In operation, the high voltage power supply module 410 converts external power, e.g., three phase normal plant power to a high DC voltage. The resonant charger module 420 charges capacitor banks in the commutator module 430 to a regulated voltage to generate pulses. The commutator module 430 shortens the pulses and increases their voltage. The compression head module 440 further temporally compresses the electrical pulses from the commutator module 430 with a corresponding increase in peak current to produce pulses with the desired risetime and voltage. These pulses are then applied across peaking capacitors and electrodes (not shown) in the laser chamber module 450. Additional details of arrangement and operation of such laser systems can be found, for example, in U.S. Pat. No. 7,079,564, titled “Control System for a Two Chamber Gas Discharge Laser” issued Jul. 18, 2006. Further details on the operation of this circuitry may be found in U.S. Pat. No. 7,002,443, titled “Method and Apparatus for Cooling Magnetic Circuit Elements” issued Feb. 21, 2006.

All patent applications, patents, and printed publications cited herein are incorporated herein by reference in their entireties, except for any definitions, subject matter disclaimers or disavowals, and except to the extent that the incorporated material is inconsistent with the express disclosure herein, in which case the language in this disclosure controls.

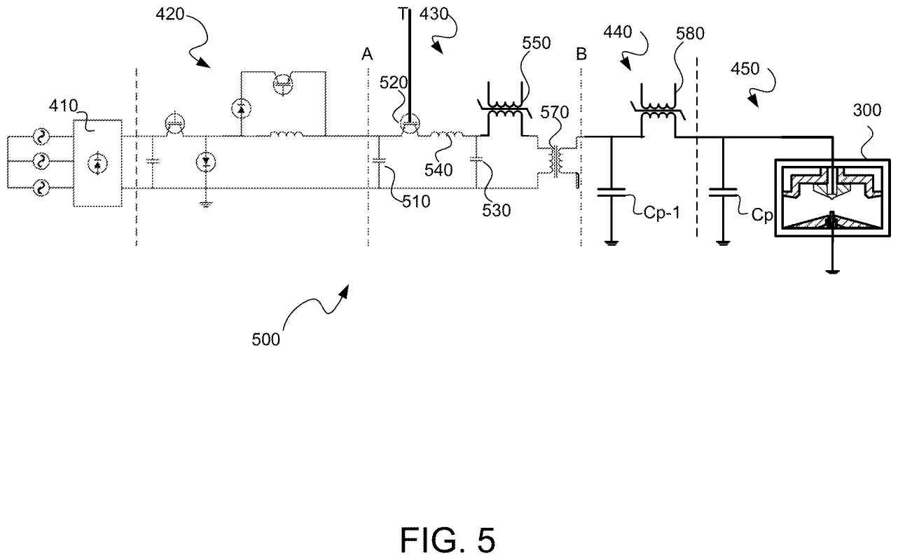

FIG. 5 is a simplified circuit diagram for certain components of an SSPPM 500 connected to a high voltage power supply module 410, the SSPPM including a resonant charger module 420, a commutator module 430, and compression module 440 such as could be used in the pulsed power circuit of FIG. 3 according to an aspect of an embodiment. The elements between dashed lines A and B comprise the circuitry implementing the commutator module 430. The high voltage power supply module 410 supplies power to the resonant charger module 420 which operates in a known manner. The pulses from the resonant charger module 420 are supplied to the commutator module 430 to a charge a capacitor 510. The capacitor 510 is usually referred to as C₀ and the voltage on the capacitor 510 is usually referred to as VC₀. When a trigger signal T is supplied to a commutator solid state switch 520, the commutator solid state switch 520 closes, discharging the capacitor 510 to a capacitor 530 through a charging inductance 540. The capacitor 530 is usually referred to as C₁ and the voltage across the capacitor 530 is usually referred to as VC₁. The voltage is held on the capacitor 530 until a saturable reactor 550, functioning as a magnetic switch, saturates and discharges the capacitor 530 into a capacitor Cₚ₋₁ in the compression head module 440 through a transformer 570. The compression head module 440 also typically contains one or more saturable reactors 580 functioning as magnetic switches operating in a manner similar to that just described.

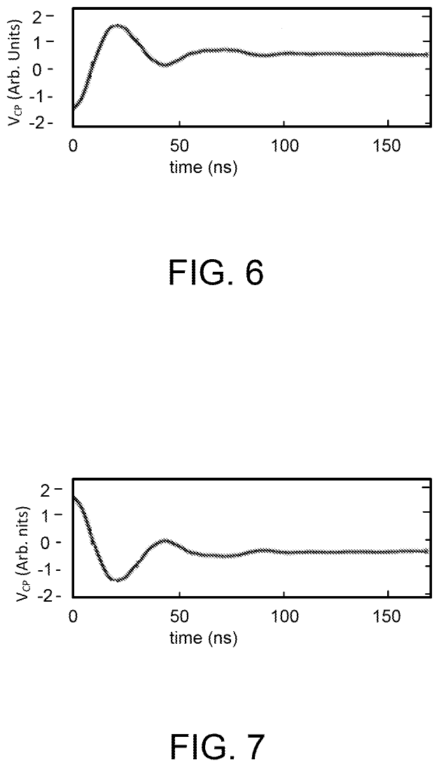

Ultimately the peaking capacitor Cₚ in the laser chamber module 450 is pulse charged by the SSPPM 500. Current flow begins to build, flowing out of the peaking capacitor Cₚ into the discharge between the electrodes modeled as a capacitance. The voltage on the peaking capacitor Cₚ passes through zero, and the current through the discharge begins to subside but continued current flow out of the peaking capacitor Cₚ forces the voltage on the peaking capacitor Cₚ, V_{CP}, to reverse polarity. A graph of the voltage V_{CP} is shown in FIG. 6. As can be seen, the voltage at t=0 is a negative peak, following by a positive overshoot and then a series of attenuating oscillations. The time derivative of V_{CP}, dV_{CP}/dt, before the negative peak is initially negative, making this a negative-going pulse. In other words, the pulse is negative while the discharge is occurring.

Further information about the SSPPM can be gleaned from U.S. Pat. No. 7,167,499, issued Jan. 23, 2007, titled “Very High Energy, High Stability Gas Discharge Laser Surface Treatment System.”

As described, conventionally, the SSPPM 500 is adapted to apply a negative-going (initially negative dV_{CP}/dt) pulse to the upper electrode (conventional cathode) 310. The lower electrode 320, being at a higher relative potential with respect to the upper electrode 310 during a pulse, exhibits a greater tendency to be innately passivated than the upper electrode 310.

For example, during manufacturing a step of conditioning the electrodes referred to passivation is carried out. Passivation for the cathode is carried out by causing electrons and F− ions to strike and make the surface less reactive with fluorine. The passivation process must be carried out long enough to passivate the conventional cathode even though the conventional anode is already passivated at this point.

Once a chamber is deployed in the field the passivation layer of its electrode discharge surfaces degrades. Counteracting this degradation to some extent is an innate repassivation due to dV_{CP}/dt negative peak passivation in which the nature of the negative pulse applied to the cathode permits a sufficient number of electrons and F ions having sufficient momentum to strike and passivate the upper electrode surface. In use, however, the cathode discharge surface is more susceptible to ion bombardment damage again because its passivation is less robust than the conventional anode passivation.

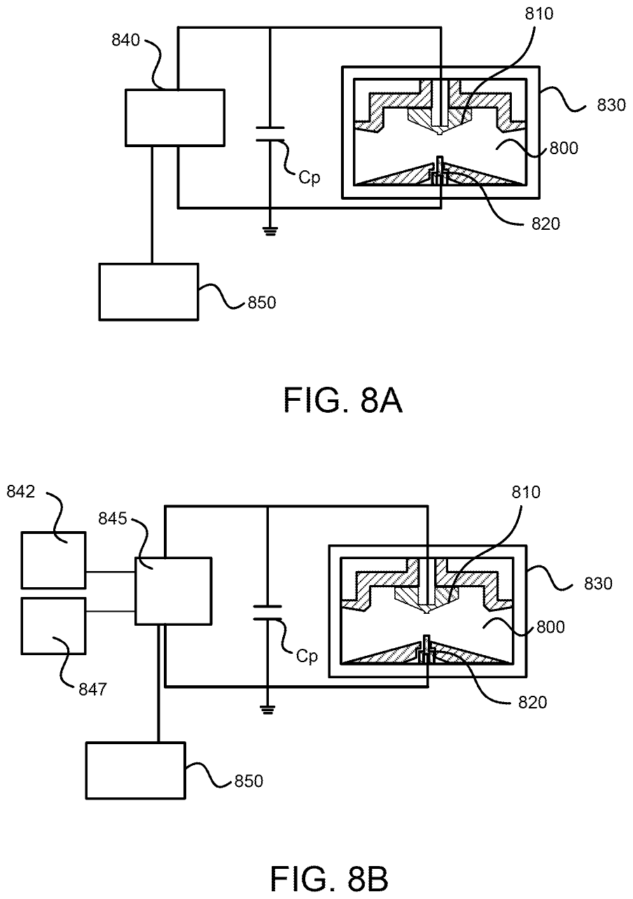

According to an aspect of an embodiment, during manufacturing passivation each chamber is operated for a first interval at “normal” polarity (dV_{CP}/dt negative peak) (FIG. 6) and for a second interval at reversed polarity (dV_{CP}/dt positive peak) (FIG. 7). Using this method, both electrodes of each new chamber can be fully matured with many fewer pulses (e.g., few hundred million pulses instead of few billion pulses) before deployment.

According to another aspect of an embodiment, during manufacturing a conditioning operation is carried out in which every new electrode is placed in a conditioning rig and pre-fired as the anode (i.e., with a polarity which is positive with respect to an opposed electrode) before the new electrode is installed in its chamber.

According to another aspect of an embodiment, after the chamber has been put in service it can also be fired from time to time with reverse polarity. According to one aspect, the EVI of the chamber is monitored and an interval of reverse polarity operation is ordered when the EVI exceeds a predetermined threshold. Alternatively, the interval of reverse polarity operation may be made to occur at set operational milestones (e.g., number of pulses, number of pulses at low voltage operation, etc.) which are determined a priori to correspond to pulse counts and conditions where EVI can be predicted to become unstable. The intervals of reverse polarity maybe between bursts of pulses of normal polarity. According to an aspect of an embodiment, the SSPPM system for the electrodes is adapted to switch polarity between pulses and even on a pulse-by-pulse basis to permit essentially continuous repassivation of the electrodes.

According to another aspect of an embodiment, the SSPPM system is designed so the laser is capable of switching polarity under control of a properly programmed controller. The controller is configured to dynamically monitor laser EVI behavior and reverse the SSPPM firing polarity once EVI significance exceeds a predetermined level. This can be accomplished through alteration of the SSPPM 500 transformer 570 secondary routing. It may also include alteration of the SSPPM 500 by changing the polarity of the commutator module 430. It may also include alteration of the supply compression head module 440 magnetic switches. It will be apparent to one of ordinary skill in the art that there are multiple ways in which the SSPPM 500 can be modified to controllably generate reverse polarity pulses. As an alternative the SSPPM 500 can include first circuitry for generating conventional negative-going pulses and second circuitry for generating positive-going (initially positive dV_{CP}/dt) pulses and a switching element to supply power either to one or the other of the first and second circuitry or supply an output from one or the other of the first and second circuitry.

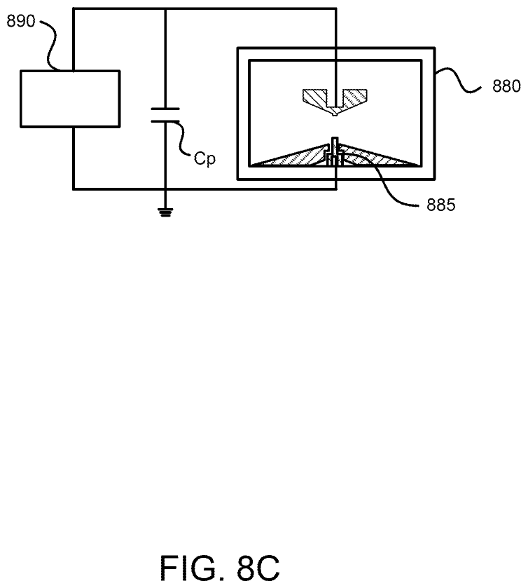

FIG. 8A is a partially schematic functional block diagram of an arrangement for conditioning electrodes as part of an electrode manufacturing process. In the arrangement shown, a chamber 800 with an upper electrode 810 and a lower electrode 820 is placed in a passivation rig 830. A power supply 840 supplies pulses to the electrodes 810, 820. A controller 850 controls the polarity of the pulses applied to the electrodes in the chamber 800. Thus, as part of a passivating step of preparing the electrodes, the power supply 840 will for a certain interval produce conventional negative-going pulses and then, when instructed to do so by the controller 850, produce a series of positive-going pulses. During the negative-going pulses the upper electrode 810 functions as a conventional cathode and the lower electrode 820 functions as a conventional anode. During the positive-going pulses the upper electrode 810 functions as a conventional anode and the lower electrode 820 functions as a conventional cathode. According to an aspect of an embodiment, the number of negative-going pulses applied during conditioning is in a predetermined ratio to a number, e.g., 1:1, of positive-going pulses applied during conditioning. The negative-going pulses and positive-going pulses also can be produced alternately on a pulse-by-pulse basis if so desired. Using both negative-going pulses and positive-going pulses shortens the overall initial passivation time because the upper electrode 810 is more efficiently passivated when functioning as a conventional anode.

FIG. 8B shows an alternative arrangement in which a control signal from the controller 850 controls operation of a switch 845 which connects the electrode 810 to either a first pulsed power supply 842 generating pulses having a first polarity or a second pulsed power supply 847 generating pulses having a second polarity reversed from the first polarity.

FIG. 8C shows an arrangement in which an electrode 880 to be used as an upper electrode or a bottom electrode is conditioned before being installed in a chamber by being placed in a conditioning rig 885 and being electrically connected to a pulsed power supply 890 as an anode. Thus, in this implementation, if used, every electrode undergoes passivation as an anode regardless of whether is ultimately to be used as an upper electrode or lower electrode.

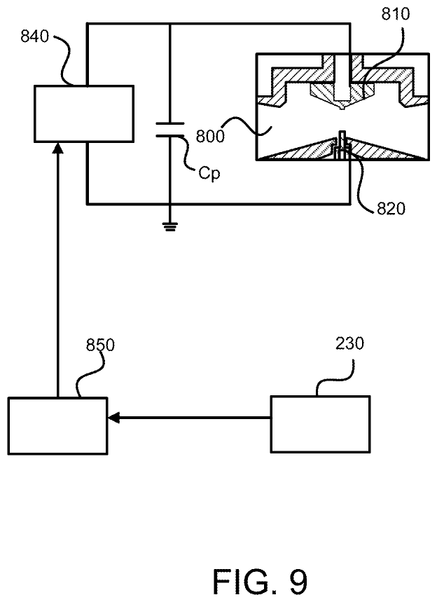

FIG. 9 is a partially schematic functional block diagram of an arrangement for conditioning electrodes after the chamber has been put in use. In the arrangement shown, a power supply 840 supplies negative-going or positive going pulses to the electrodes 810, 820 in the chamber 800. A controller 850 controls the polarity of the pulses applied to the electrodes in the chamber 800. A metrology unit such as the BAM 230 described above in connection with FIG. 2 measures the pulse energy and relays it to the controller 850. The controller 850 compares the beam output energy to determine whether there is significant EVI (e.g., above a predetermined threshold in terms of magnitude, frequency of occurrence, or both) indicating that repassivating the upper electrode may be beneficial. The controller 850 then instructs the power supply 840 to produce a series of positive-going pulses. Applying positive-going pulses efficiently repassivates the upper electrode 810. The controller 850 after a set time or in response to a set condition (e.g., EVI occurring only within acceptable parameters) can then instruct the supply 840 to again start producing conventional negative-going pulses. The radiation produced during periods of reversed polarity operation can be used for photolithography.

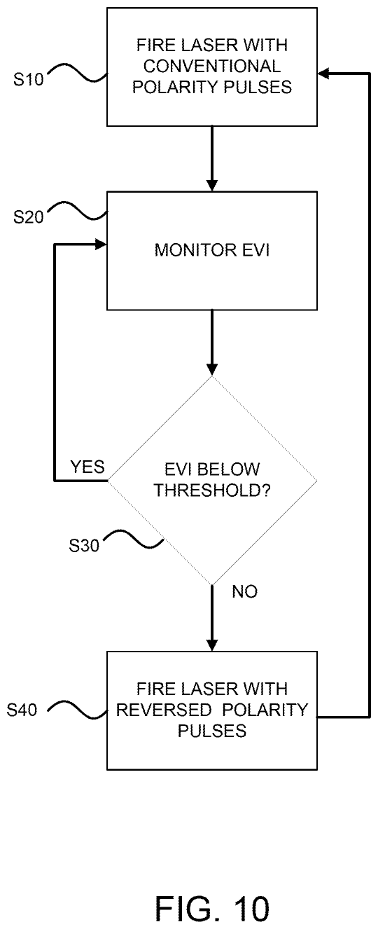

FIG. 10 is a flowchart showing an example of a method of operating an arrangement such as that shown in FIG. 5. In a step S10 the laser is fired using conventional (negative-going) pulses for a certain operational period. While the laser is being fired, i.e., while carrying out step S10, in a step S20 energy voltage instability (EVI) is monitored. In a step S30 it is determined whether some characteristic of the EVI (e.g., magnitude, frequency of occurrence) exceeds a predetermined threshold of acceptability. It will be understood that this predetermined threshold may vary depending on certain factors such as the age of the chamber, operating requirements, etc. If it is determined that the laser is still operating within acceptable EVI parameters then steps S10, S20 and S30 continue. If it is determined that the laser is not operating within acceptable EVI parameters then in a step S40 the laser is operated with reversed polarity (positive-going) pulses. Performance of step S40 continues, for example, for a period of time known a priori to be sufficient to restore passivation of the conventional cathode. Then the process reverts to step S10 to resume normal operations.

The above description includes examples of multiple embodiments. It is, of course, not possible to describe every conceivable combination of components or methodologies for purposes of describing the aforementioned embodiments, but one of ordinary skill in the art may recognize that many further combinations and permutations of various embodiments are possible. Accordingly, the described embodiments are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

The embodiments can be further described using the following clauses:

1. A pulsed power supply for a laser discharge chamber including a first electrode and a second electrode, the pulsed power supply having a first state in which the pulsed power supply generates and supplies to the first electrode at least one pulse having a first polarity and a second state in which the pulsed power supply generates and supplies to the first electrode at least one reverse polarity pulse having a second polarity, the second polarity being opposite to the first polarity.

2. The pulsed power supply of clause 1 wherein the power supply is adapted to transition between the first state and the second state in response to a control signal.

3. A laser comprising:
a discharge chamber;
a first electrode positioned at least partially within the discharge chamber;
a second electrode positioned at least partially within the discharge chamber, the first electrode having a first discharge surface and the second electrode having a second discharge surface, the first discharge surface and the second discharge surface being arranged to confront one another across a gap; and
a pulsed power supply arranged to generate and supply pulses of electrical energy to the first electrode,
wherein the pulsed power supply has a first state in which it generates and supplies to the first electrode a first plurality of pulses having a first polarity and a second state in which the pulsed power supply generates and supplies to the first electrode a second plurality of pulses having a second polarity, the second polarity being opposite to the first polarity.

4. The laser of clause 3 further comprising
a metrology unit arranged to measure and produce an output indicative of a characteristic of an energy voltage instability (EVI) of at least some of the first plurality of pulses, and
a control unit arranged to receive the output and adapted to generate a control signal based on the characteristic of the EVI of at least some of the first plurality of pulses,
wherein the pulsed power supply is arranged to receive the control signal and adapted to transition from the first state to the second state in response to the control signal.

5. The laser of clause 4 wherein the characteristic of the EVI is a magnitude of the EVI.

6. The laser of clause 4 wherein the characteristic of the EVI is a frequency of occurrence of the EVI.

7. The laser of clause 3 further comprising
a pulse counter for determining a pulse count indicating an operating age of the laser in terms of number of pulses, and
a control unit arranged to receive the pulse count and adapted to generate a control signal based on the pulse count reaching a predetermined value,
wherein the pulsed power supply is arranged to receive the control signal and adapted to transition from the first state to the second state in response to the control signal.

8. A laser comprising:
a discharge chamber;
an upper electrode positioned at least partially within the discharge chamber;
a lower electrode positioned at least partially within the discharge chamber, the upper electrode having an upper electrode discharge surface and the lower electrode having a lower electrode discharge surface, the upper electrode discharge surface and the lower electrode discharge surface being arranged to confront one another across a gap; and
a pulsed power supply arranged to generate and supply pulses of electrical energy to the upper electrode,
wherein the pulsed power supply has a first state in which the pulsed power supply generates and supplies to the upper electrode a plurality of negative-going pulses and a second state in which the pulsed power supply generates and supplies to the upper electrode a plurality of positive-going pulses.

9. The laser of clause 8 further comprising
a metrology unit arranged to measure and produce an output indicative of an output energy of the laser, and
a control unit arranged to receive the output and adapted to determine one or more EVI characteristics from the output and to generate a control signal based on the one or more EVI characteristics of the plurality of negative-going pulses,
wherein the pulsed power supply is arranged to receive the control signal and adapted to transition from the first state to the second state in response to the control signal.

10. A method of operating a pulsed power supply for a laser discharge chamber including a first electrode and a second electrode, comprising:
causing the pulsed power supply to operate in a first state in which it generates and supplies to the first electrode at least one pulse having a first polarity; and
causing the pulsed power supply to transition to a second state in which the pulsed power supply generates and supplies to the first electrode at least one reverse polarity pulse having a second polarity, the second polarity being opposite to the first polarity.

11. The method of clause 10 wherein causing the pulsed power supply to transition to the second state comprises receiving a control signal.

12. A method of operating a laser, the laser comprising a discharge chamber; a first electrode positioned at least partially within the discharge chamber, and a second electrode positioned at least partially within the discharge chamber, the first electrode having a first discharge surface and the second electrode having a second discharge surface, the first discharge surface and the second discharge surface being arranged to confront one another across a gap, and a pulsed power supply arranged to provide pulses of electrical energy to the first electrode, the method comprising:
causing the pulsed power supply to operate in a first mode in which the pulsed power supply supplies the first electrode with a first sequence of pulses having a first polarity; and
causing the pulsed power supply to transition to operate in a second mode in which the pulsed power supplies to the first electrode a second sequence of pulses having a second polarity, the second polarity being opposite to the first polarity.

13. The method of clause 12 further comprising
measuring and producing an output indicative of an output energy of the laser,
determining at least one EVI characteristic of the first sequence of pulses from the output, and
generating a control signal based on the EVI characteristic,
wherein causing the pulsed power supply to transition comprises the pulsed power supply receiving the control signal and transitioning from the first mode to the second mode in response to the control signal.

14. The method of clause 13 wherein the at least one EVI characteristic is a magnitude of the EVI.

15. The method of clause 13 wherein the at least one EVI characteristic is a frequency of occurrence of the EVI.

16. A method of operating a laser, the laser including a discharge chamber, an upper electrode positioned at least partially within the discharge chamber, and a lower electrode positioned at least partially within the discharge chamber, the upper electrode having an upper electrode discharge surface and the lower electrode having a lower electrode discharge surface, the upper electrode discharge surface and the lower electrode discharge surface being arranged to confront one another across a gap, and a pulsed power supply arranged to generate and supply pulses of electrical energy to the upper electrode, the method comprising:
causing the pulsed power supply to operate in a first mode in which the pulsed power generates and supplies to the upper electrode a plurality of negative-going pulses; and
causing the pulsed power supply to transition to a second mode in which the pulsed power supply generates and supplies to the upper electrode a plurality of positive-going pulses.

17. The method of clause 16 further comprising
measuring and producing an output indicative of at least one characteristic of EVI of the laser, and generating a control signal based on the at least one EVI characteristic of at least some of the plurality of negative-going pulses,
wherein the pulsed power supply is arranged to receive the control signal and adapted to transition from the first mode to the second mode in response to the control signal.

18. A method of conditioning a first electrode and a second electrode, comprising:
causing a pulsed power supply to supply a first sequence of pulses having a first polarity to the first electrode; and
causing the pulsed power supply to supply a second sequence of pulses to the first electrode, the pulses in the second sequence of pulses having a second polarity, the second polarity being opposite to the first polarity.

19. The method of clause 18 wherein a number of pulses having the first polarity applied during conditioning is in a predetermined ratio to a number of pulses having the second polarity applied during conditioning.

20. A method of a conditioning an electrode to be conditioned for use in a chamber, the method comprising:
providing a test rig including an upper electrode and a pulsed power supply connected to supply negative-going pulses to the upper electrode;
placing the electrode to be conditioned in the test rig and connecting the electrode to be conditioned to the pulsed power supply as a lower electrode;
applying pulses to the upper electrode to passivate the electrode to be conditioned to create a conditioned electrode;
removing the conditioned electrode from the test rig; and
installing the conditioned electrode in the chamber as an upper electrode or a lower electrode.

21. A pulsed power supply system for a laser discharge chamber including a first electrode and a second electrode, the pulsed power supply system comprising:
a pulsed power supply adapted to have a first state in which the pulsed power supply generates and supplies to the first electrode a first plurality of pulses having a first polarity and a second state in which the pulsed power supply generates and supplies to the first electrode a second plurality of pulses having a second polarity, the second polarity being opposite to the first polarity;
a metrology unit arranged to measure and produce an output indicative of at least one characteristic of an EVI of at least some of first plurality of pulses, and
a control unit arranged to receive the output and adapted to generate a control signal based at least in part on the output,
wherein the pulsed power supply is arranged to receive the control signal and adapted to transition from the first state to the second state in response to the control signal.

22. The pulsed power supply system of clause 21 wherein the at least one characteristic of the EVI is a magnitude of the EVI.

23. The pulsed power supply system of clause 21 wherein the at least one EVI characteristic is a frequency of occurrence of the EVI.

The above described implementations and other implementations are within the scope of the following claims.

1-2. (canceled)

3. A laser comprising:
a discharge chamber;
a first electrode positioned at least partially within the discharge chamber;
a second electrode positioned at least partially within the discharge chamber, the first electrode having a first discharge surface and the second electrode having a second discharge surface, the first discharge surface and the second discharge surface being arranged to confront one another across a gap; and
a pulsed power supply arranged to generate and supply pulses of electrical energy to the first electrode,
wherein the pulsed power supply has a first state in which it generates and supplies to the first electrode a first plurality of pulses having a first polarity and a second state in which the pulsed power supply generates and supplies to the first electrode a second plurality of pulses having a second polarity, the second polarity being opposite to the first polarity.

4. The laser of claim 3 further comprising
a metrology unit arranged to measure and produce an output indicative of a characteristic of an energy voltage instability (EVI) of at least some of the first plurality of pulses, and
a control unit arranged to receive the output and adapted to generate a control signal based on the characteristic of the EVI of at least some of the first plurality of pulses,
wherein the pulsed power supply is arranged to receive the control signal and adapted to transition from the first state to the second state in response to the control signal.

5. The laser of claim 4 wherein the characteristic of the EVI is a magnitude of the EVI.

6. The laser of claim 4 wherein the characteristic of the EVI is a frequency of occurrence of the EVI.

7. The laser of claim 3 further comprising
a pulse counter for determining a pulse count indicating an operating age of the laser in terms of number of pulses, and
a control unit arranged to receive the pulse count and adapted to generate a control signal based on the pulse count reaching a predetermined value,
wherein the pulsed power supply is arranged to receive the control signal and adapted to transition from the first state to the second state in response to the control signal.

8.-11. (canceled)

12. A method of operating a laser, the laser comprising a discharge chamber; a first electrode positioned at least partially within the discharge chamber, and a second electrode positioned at least partially within the discharge chamber, the first electrode having a first discharge surface and the second electrode having a second discharge surface, the first discharge surface and the second discharge surface being arranged to confront one another across a gap, and a pulsed power supply arranged to provide pulses of electrical energy to the first electrode, the method comprising:
causing the pulsed power supply to operate in a first mode in which the pulsed power supply supplies the first electrode with a first sequence of pulses having a first polarity; and
causing the pulsed power supply to transition to operate in a second mode in which the pulsed power supply supplies to the first electrode a second sequence of pulses having a second polarity, the second polarity being opposite to the first polarity.

13. The method of claim 12 further comprising
measuring pulse energy;
producing an output indicative of an output energy of the laser,
determining at least one EVI characteristic of the first sequence of pulses from the output, and
generating a control signal based on the at least one EVI characteristic,
wherein causing the pulsed power supply to transition comprises receiving the control signal, by the pulsed power supply, and transitioning the operation from the first mode to the second mode in response to the control signal.

14. The method of claim 13 wherein the at least one EVI characteristic is a magnitude of the EVI or a frequency of occurrence of the EVI.

15-20. (canceled)

21. A pulsed power supply system for a laser discharge chamber including a first electrode and a second electrode, the pulsed power supply system comprising:
a pulsed power supply adapted to have a first state in which the pulsed power supply generates and supplies to the first electrode a first plurality of pulses having a first polarity and a second state in which the pulsed power supply generates and supplies to the first electrode a second plurality of pulses having a second polarity, the second polarity being opposite to the first polarity;
a metrology unit arranged to measure and produce an output indicative of at least one characteristic of at least some of first plurality of pulses, and
a control unit arranged to receive the output and adapted to generate a control signal based at least in part on the output,
wherein the pulsed power supply is arranged to receive the control signal and adapted to transition from the first state to the second state in response to the control signal.

22. The pulsed power supply system of claim 21 wherein the at least one characteristic is a magnitude an EVI or a frequency of occurrence of the EVI.

23. (canceled)

24. The pulsed power supply system of claim 21, wherein the at least one characteristic includes a number of the first plurality of pulses at a low voltage operation.

25. The pulsed power supply system of claim 21, wherein the pulsed power supply is adapted to transition from the first state to the second state between pulses.

26. The pulsed power supply system of claim 21, wherein the first electrode and the second electrode are passivated and repassivated during a switch between the first state and the second state.

27. The pulsed power supply system of claim 21, wherein the first plurality of pulses includes a series of negative-going pulses and the second polarity of pulses includes a series of positive-going pulses.

28. The pulsed power supply system of claim 27, wherein a ratio of a number of the series of negative-going pulses to that of the series of positive-going pulses is 1:1.

29. The pulsed power supply system of claim 21, further comprising a peaking capacitor, wherein the series of negative-going pulses is defined by a time derivative of a voltage of the peaking capacitor.

30. The pulsed power supply system of claim 21, wherein the first electrode undergoes a same passivation as the second electrode.

31. The pulsed power supply system of claim 21, wherein the first electrode functions as a cathode and the second electrode functions as an anode in the first state, and the first electrode functions as the anode and the second electrode functions as the cathode in the second state.

32. The pulsed power supply system of claim 21, further comprising a switch, a first pulsed power supply, and a second pulsed power supply, wherein the first electrode is connected to either the first pulsed power supply or the second pulsed power supply.

33. The pulsed power supply system of claim 21, wherein the laser discharge chamber is a master oscillator.
